(19) United States
(12) Patent Application Publication
(10) Pub. No.: US 2006/0148163 A1
(43) Pub. Date: Jul. 6, 2006

(54) Method of forming gate insulation layers of different characteristics

(76) Inventors: Karsten Wieczorek, Dresden (DE); Thorsten Kammler, Ottendorf-Okrilla (DE); Carsten Reichel, Freiberg (DE)

Correspondence Address: WILLIAMS, MORGAN & AMERSON, 10333 RICHMOND, SUITE 1100, HOUSTON, TX, 77042, US

(21) Appl. No.: 11/196,881

(22) Filed: Aug. 4, 2005

(30) Foreign Application Priority Data
Dec. 30, 2004 (DE) 10 2004 063 532.3

(51) Int. Cl. H01L 21/8238; H01L 21/336; H01L 21/31

(52) U.S. Cl. 438/216; 438/778; 438/287

(57) ABSTRACT

The present invention describes a method for forming different types of gate insulation layers, wherein the formation of one type of gate insulation layer is highly decoupled from the formation of the other type of gate insulation layer. Thus, in some embodiments, critical oxidation processes may finely be tuned on an individual basis. This is accomplished by providing a mask layer that may substantially prevent any impact on an initially made insulation layer during a subsequent manufacturing process of a second gate insulation layer.

### BACKGROUND OF THE INVENTION

1. Field of the Invention

Generally, the present invention relates to the field of fabricating integrated circuits, and, more particularly, to the formation of ultra-thin dielectric layers, such as gate insulation layers, having a well-defined difference in certain characteristics, such as the thickness, at different substrate locations.

2. Description of the Related Art

Integrated circuits are, due to their relatively low cost and high performance, increasingly used in many types of devices, thereby allowing superior control and operation of those devices. Due to economic reasons, semiconductor manufacturers are frequently confronted with the task of steadily improving performance of these integrated circuits with every new device generation launched onto the market. Improving the device performance, however, typically requires a reduction in size of the individual circuit elements of the integrated circuit, thereby not only improving the performance of individual circuit elements but also significantly increasing the overall functionality of the integrated circuit with respect to the available chip area.

In present state technologies, the critical dimension, i.e., a minimum dimension that has to be reliably and reproducibly patterned onto a certain device layer, may be on the order of approximately 50 nm and even less in sophisticated devices. For instance, a gate length of a field effect transistor of a 90 nm technology has a size of approximately 50 nm. In producing circuit elements of this order of magnitude, process engineers are, along with many other issues especially arising from the reduction of feature sizes, faced with the task of providing extremely thin dielectric layers on an underlying material layer, wherein certain characteristics of the dielectric layer, such as permittivity and/or resistance against charge tunneling and the like, have to meet specific requirements, without sacrificing the physical properties of the underlying material layer.

One important example in this respect is the formation of ultra-thin gate insulation layers of field effect transistors, such as MOS transistors. The gate insulation layer of a transistor has a significant impact on the performance of the transistor. As is commonly known, reducing the size of a field effect transistor, that is, reducing the length of a conductive channel that forms in a surface portion of a semiconductor region by applying a control voltage to a gate electrode formed on the gate insulation layer, also requires the reduction of the thickness of the gate insulation layer to maintain the required coupling capacitance between the gate electrode and the channel region.

Presently, and in the near future, most of the highly sophisticated integrated circuits such as CPUs, memory chips and the like are and will be based on silicon, e.g., bulk silicon and/or silicon-on-insulator substrates. Therefore, silicon dioxide has been preferably used as the material for the gate insulation layer due to the well known and superior characteristics of the silicon dioxide/silicon interface. For a channel length on the order of well below 100 nm, however, the thickness of the gate insulation layer has to be reduced to about 2 nm or even less in order to maintain the required controllability of the transistor operation. Decreasing the thickness of the silicon dioxide gate insulation layer, however, leads to an increased leakage current, thereby resulting in an increase of static power consumption and even in a complete failure of various functional circuit blocks as the leakage current exponentially increases for a linear reduction of the oxide layer thickness.

Therefore, in some approaches, great efforts are presently being made to replace silicon dioxide with a dielectric material exhibiting a significantly higher permittivity so that a thickness thereof may be remarkably greater than the thickness of a corresponding silicon dioxide layer providing the same capacitance. A thickness of a dielectric layer for obtaining a specified capacitive coupling will also be referred to as a capacitance equivalent thickness and determines the thickness that would be required for a silicon dioxide layer. It turns out however, that it is difficult to incorporate materials of high permittivity into the conventional integration process, and more importantly, the provision of a material of high permittivity as a gate insulation layer seems to have a significant influence on the carrier mobility in the underlying region, thereby reducing the carrier mobility and thus the drive current capability of the transistor. Hence, although an improvement of the static transistor characteristics may be obtained by providing a thick material of increased permittivity, at the same time an unacceptable degradation of the dynamic behavior presently makes this approach less than desirable.

In other approaches that are currently practiced, appropriate circuit designs are considered in which the gate insulation layers are provided with two different thicknesses, wherein the sophisticated ultra-thin gate insulation layer is provided in critical circuit blocks, such as CPU cores and the like, whereas other circuit blocks may receive a thicker gate insulation layer, thereby significantly relaxing the issue of increased leakage currents. Since logic blocks having an increased gate insulation thickness may, however, be also present in speed critical signal paths, the corresponding transistors are required to provide a substantial current drive capability, which is generally accomplished by a slightly increased supply voltage compared to the transistor devices that have the sophisticated ultra-thin but tunneling-promoting gate insulation layers. Consequently, tightly set reliability objectives, such as low defect rates in the gate insulation layer as well as in the underlying semiconductor layer and the like, have to be met both by the thin gate insulation layer and the gate insulation layer of increased thickness as the latter has to provide for reliable operation at an increased supply voltage. Consequently, an extremely careful thickness targeting for both types of insulation layers is essential for achieving high device performance and reliability. However, in conventional process flows for forming sophisticated gate insulation layers of different thickness, a strong correlation exists for the final gate insulation layer of increased thickness with respect to the ultra-thin gate insulation layer.

With reference to FIGS. 1a-1e, a typical conventional process will now be described in more detail to more clearly illustrate the problems involved. FIG. 1a is a schematic cross-sectional view of a silicon-based semiconductor device 100 in a manufacturing stage prior to the formation of transistor elements receiving a silicon dioxide gate insulation layer of different thickness. The semiconductor device 100 comprises a first device region 110a and a second device region 110b, which are formed in an appropriate substrate 101 such as a silicon bulk substrate, a silicon-on-insulator (SOI) substrate and the like. The regions 110a and 110b may be separated by any intermediate device region, including other functional areas, insulating areas and the like. In this example, the intermediate region is represented by an isolation structure 102, which typically has a lateral dimension that is significantly greater than a lateral size of the regions 110a and 110b. The region 110a comprises a substantially crystalline semiconductor region 103a having formed thereon a silicon dioxide gate insulation layer 104a with a specified thickness 105. Similarly, the region 110b comprises a substantially crystalline semiconductor region 103b having formed thereon a silicon dioxide gate insulation layer 104b with the specified thickness 105. Typically, the layer thickness 105 is substantially identical in the regions 110a and 110b due to a common manufacturing process as will be described in the following.

A typical process flow for forming the device 100 as shown in FIG. 1a may comprise the following processes. After forming the isolation structure 102 by sophisticated photolithography, etch, deposition and CMP techniques, as are readily known in the art, any required implantation steps may be performed to establish a desired vertical dopant profile within the regions 103a and 103b. For convenience, any such implantation regions are not shown in FIG. 1a. After any anneal cycles for activating the dopants and healing crystalline defects in the regions 103a and 103b, the silicon dioxide gate insulation layers 104a and 104b may be formed, for instance, by sophisticated thermal oxidation processes, wherein process parameters, such as temperature, oxygen contents and process time are adjusted to obtain the desired thickness 105. Hereby, the thermal growth process may be performed in such a way that the number of any defects in the layers 104a and 104b are kept at a desired low level.

FIG. 1b schematically shows the device 100 in a further advanced manufacturing stage. Here, the device 100 is shown with a resist mask 106 covering the region 110b while exposing the region 110a. Moreover, the silicon dioxide layer 104a is removed, thereby exposing a surface 113a of the semiconductor region 103a. The resist mask 106 may be formed by well-known lithography techniques and the removal of the silicon dioxide layer 104a may be performed on the basis of well-established wet chemical processes, using for instance fluoric acid (HF). Thereafter, the resist mask 106 may be removed by well-established processes, such as treatments in an oxygen plasma with subsequent clean processes to remove contaminants from the exposed crystalline region 103a and from the surface of the silicon dioxide layer 104b. During this process of removal of the resist mask 106 and cleaning of the exposed surface portions, material of the silicon dioxide layer 104b is also removed, thereby reducing the thickness thereof.

FIG. 1c schematically shows the device 100 after completion of the above-described removal and clean sequence. Consequently, the device 100 comprises the region 110a with a clean surface that is ready for receiving a silicon dioxide gate insulation layer of a desired thickness while the region 110b comprises the layer 104b having a reduced thickness 105r. Thereafter, the device 100 is subjected to a further oxidation process performed with specified process parameters to form an oxide of specified thickness above the region 103a and also increasing the thickness 105r of the layer 104b.

FIG. 1d schematically shows the device 100 after this oxidation process. Thus, the device 100 comprises a silicon dioxide gate insulation layer 114a having a thickness 105a which may be approximately 2 nm or even less in sophisticated devices, whereas the gate insulation layer 104b is now re-oxidized to its final thickness 105b. For high performance applications, both silicon dioxide gate insulation layers 114a and 104b need to be grown with an accuracy of a few tenths of an Angstrom. Accordingly, any change required in the gate insulation layer 114a, for instance, in view of device adaptation and the like, entails a similar change of the gate insulation layer 104b which may, however, not be appropriate for the device under consideration. Due to the strong interdependence of the gate insulation layer 114a and the gate insulation layer 104b caused by the above manufacturing sequence, a corresponding effort is necessary in adapting the process flow described above for re-targeting the otherwise undesired thickness to the finally desired layer thickness 105b, thereby, significantly lowering process efficiency and flexibility.

Thereafter, the process flow may be continued by depositing polysilicon as a gate electrode material which is then patterned by sophisticated techniques including advanced photolithography and trim etch processes.

FIG. 1e schematically shows the device 100 with a gate electrode 107a formed on the silicon dioxide gate insulation layer 114a and a gate electrode 107b formed on the silicon dioxide gate insulation layer 104b.

In view of the situation described above, a need exists for an improved technique that enables the formation of insulating layers with different characteristics while avoiding one or more of the problems identified above or at least reducing the effects of one or more of these problems.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique that enables the formation of dielectric layers of different characteristics, such as, in particular embodiments, of different thickness, wherein a characteristic of a first dielectric layer may be adjusted substantially independently from the characteristics of a second dielectric layer, thereby providing an enhanced flexibility in a manufacturing process flow. In illustrative embodiments, the dielectric layers of different characteristics, such as different thicknesses, may represent gate insulation layers of highly sophisticated transistor elements requiring the adjustment of the respective thickness with an accuracy of a few tenths of an Angstrom.

According to one illustrative embodiment of the present invention, a method comprises forming a first dielectric layer having a first specified characteristic on a first semiconductor region and a second semiconductor region, wherein the first and second semiconductor regions are formed on a substrate. Moreover, a mask layer is formed above the substrate to expose a first portion of the first dielectric layer located above the first semiconductor region and to cover a second portion of the first dielectric layer that is located above the second semiconductor region. Then, the first portion of the dielectric layer is removed. Finally, a second dielectric layer is formed on the semiconductor region, wherein the second dielectric layer has a second specified characteristic that differs from the first characteristic. During the formation of the second dielectric layer, the mask layer prevents the second dielectric layer from forming on the second portion of the first dielectric layer.

### BRIEF DESCRIPTION OF THE DRAWINGS

The invention may be understood by reference to the following description taken in conjunction with the accompanying drawings, in which like reference numerals identify like elements, and in which:

FIGS. 1a-1e schematically show a cross-sectional view of a semiconductor device receiving two gate oxide layers of different thickness during various manufacturing stages of a conventional process flow;

FIGS. 2a-2h schematically show a semiconductor device during various manufacturing stages in accordance with illustrative embodiments of the present invention, wherein different dielectric layers of different thickness and high accuracy are formed in a highly independent fashion; and

FIGS. 3a-3d schematically illustrate cross-sectional views of a semiconductor device during various manufacturing stages in accordance with further illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

In the following description, further illustrative embodiments will be described in more detail, wherein reference is made to dielectric layers representing gate insulation layers of transistor elements to be formed in and on specified semiconductor regions. Although the embodiments described herein are highly advantageous in the context of the application of ultra-thin gate insulation layers of sophisticated transistor elements as may be used in modern CPUs, memory devices and the like, it should be borne in mind that, in some embodiments, the dielectric layers described herein may represent gate insulation layers of less advanced transistor elements, or may represent capacitor dielectrics, or the different dielectric layers referred to herein may represent a combination of gate insulation layers having a first characteristic, such as material composition, thickness and the like, and a capacitor dielectric having a second characteristic, such as material composition, thickness and the like. Consequently, unless otherwise stated in the appended claims and explicitly referred to in further embodiments that follow, the present invention should not be restricted to gate insulation layers.

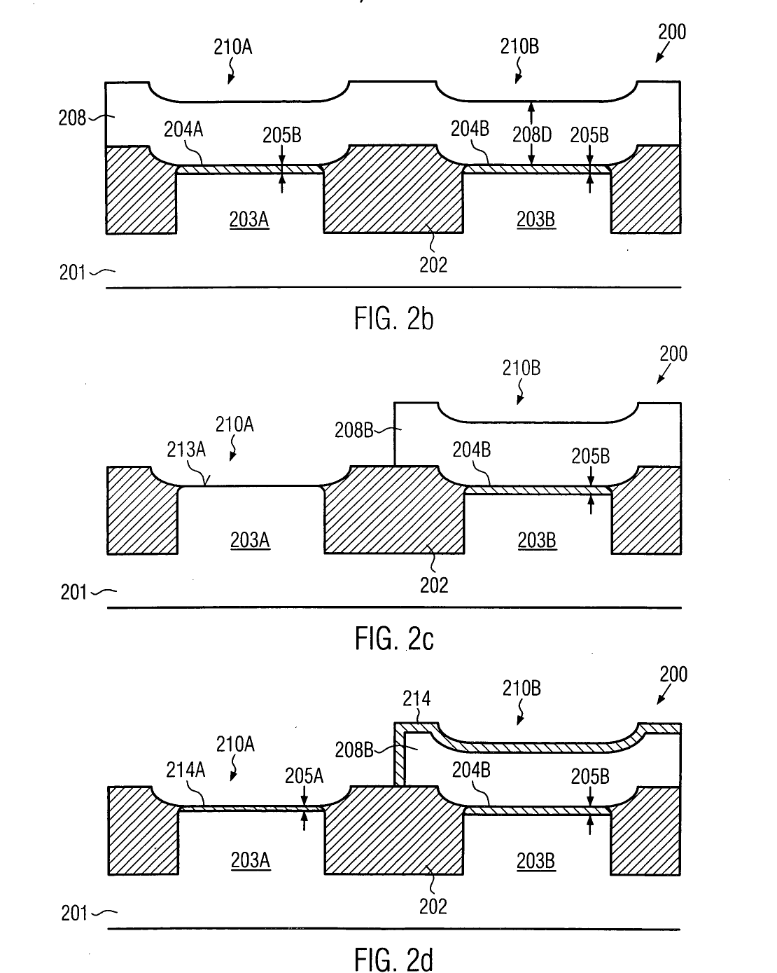

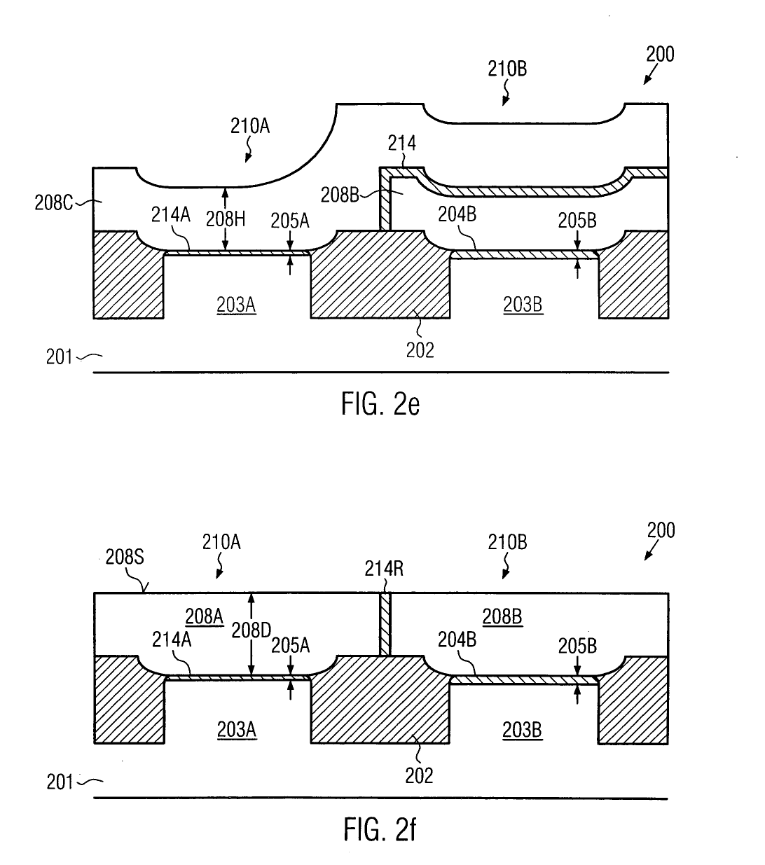

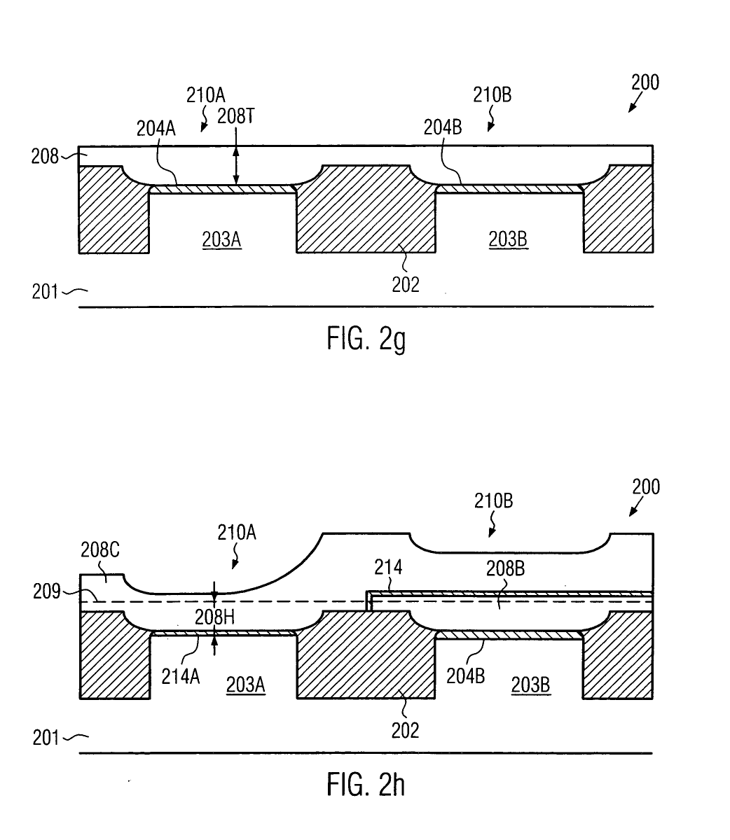

FIG. 2a schematically shows a cross-sectional view of a semiconductor device 200 during an early manufacturing stage for forming dielectric layers of different characteristics, wherein, in a particular embodiment, dielectric layers of different thickness may be formed. The semiconductor device 200 comprises a substrate 201 which may represent any appropriate substrate having formed thereon a crystalline layer that may be used for the formation of circuit elements, such as transistors, capacitors and the like. In particular embodiments, the substrate 201 may represent a bulk silicon substrate, or any other substrate having formed thereon a silicon-based semiconductor layer, or a silicon-on-insulator (SOI) substrate, since the vast majority of integrated circuits having a CMOS architecture are presently and will be in the foreseeable future fabricated on the basis of silicon.

In the substrate 201, there is defined first region 210a and second region 210b which may represent different areas within one die on the substrate 201. Thus, in some embodiments, the first region 210a may represent a region that may receive a first functional block of circuit elements, while the second region 210b may be dedicated to receiving a second functional block of circuit elements. For example, the region 210a may represent a functional block within a CPU core, while the region 210b may represent a peripheral area with respect to the core region 210a. In other embodiments, the regions 210a and 210b may more or less represent neighboring regions for receiving an individual circuit element depending on the design requirements, wherein any interposed region separating the regions 210a, 210b may have a size that is comparable with the sizes of the regions 210a, 210b. Irrespective of the spatial relationship of the regions 210a and 210b, in FIG. 2a, an isolation structure 202 is formed within the substrate 201 to separate the regions 210a and 210b. It should be appreciated, however, that the isolation structure 202 may represent any substrate region located between the regions 210a and 210b when these regions are moderately widely spaced apart.

Moreover, the isolation structure 202 may further represent an isolation structure to define respective semiconductor regions 203a and 203b within the substrate 201. In some embodiments, the isolation structure 202 may be provided in the form of a shallow trench isolation. Moreover, a first dielectric layer having, respectively, a first portion 204a and a second portion 204b is formed on the first and second semiconductor regions 203a and 203b. The first dielectric layer represented by the portions 204a and 204b has a first characteristic, which is represented in the embodiment shown by a thickness indicated as 205b which is substantially identical in both the region 203a and 203b. In sophisticated semiconductor devices based on silicon, the first dielectric layer having the portions 204a and 204b may comprise silicon dioxide and the thickness 205b may be approximately 5 nm or significantly less depending on the overall feature sizes and performance characteristics of the circuit element to be formed above the second semiconductor region 203b. In some illustrative embodiments, the portions 204a and 204b may comprise, in addition or alternatively, other materials such as nitrogen and the like to endow the portion 204b with desired characteristics in view of permittivity, charge carrier blocking and the like.

A typical process flow for forming the semiconductor device 200 as shown in FIG. 2a may comprise the following processes. After the formation of the isolation structure 202 on the basis of well-established process techniques involving photolithography, advanced etch and deposition methods, chemical mechanical polishing (CMP) and the like, implantation, anneal and cleaning processes may be performed. Thereafter, the portions 204a, 204b of the first dielectric layer may be formed, according to one particular embodiment, at least partially by an oxidation process. To this end, a well-controllable oxidation process may be performed on the basis of well-defined process parameters to precisely adjust the thickness 205b to the target or design value with the required accuracy. Corresponding process recipes for controlling the temperature, the composition and condition of the oxidizing ambient, the duration of the oxidation, and the like are well established.

After forming the portions 204a and 204b in the form of an oxide layer, further treatments may be performed to achieve the finally desires thickness 205b and/or to impart the desired characteristics to the second portion 204b. For instance, in some embodiments, the portions 204a and 204b may be oxidized to a basic thickness and thereafter a desired material may be deposited on the basic oxide layer. For example, a further oxide layer may be deposited or any other suitable material, such as silicon nitride and the like, may be deposited by any appropriate deposition technique, such as plasma enhanced chemical vapor deposition, thermal chemical vapor deposition, atomic layer deposition, and the like. In still other embodiments, the semiconductor regions 203a and 203b may be oxidized to achieve the desired thickness 205b and thereafter the resulting oxide layer portions 204a and 204b may be treated, for instance, by providing a nitrogen-containing plasma, to thereby introduce a specific amount of nitrogen into the oxide layers. In one illustrative embodiment, the portions 204a and 204b may be formed by a wet chemical oxidation on the basis of well-known oxidants. In still other embodiments, the portions 204a and 204b may be formed by highly advanced deposition techniques, for instance, by depositing semiconductor oxide under precisely controlled process parameters to adapt the thickness 205b to a specified design thickness within the required process margin.

FIG. 2b schematically shows the semiconductor device 200 with a mask layer 208 formed on the dielectric layer portions 204a and 204b. In a particular embodiment, the mask layer 208 is comprised of an electrode material, such as polysilicon, which may be used for the formation of an electrode structure above the second semiconductor region 203b. In this embodiment, the mask layer 208 may be provided with a thickness 208t that is greater than a specified design height of the electrode structure to be formed above the second semiconductor region 203b. In some illustrative embodiments, the mask layer 208 may be comprised of a first electrode material having characteristics that enhance the performance thereof when patterned to a corresponding electrode structure. For example, the mask layer 208 may be provided as a polysilicon layer including a specific dopant material with a desired concentration.

The mask layer 208 may be deposited by any appropriate deposition technique, for instance, when comprising polysilicon, the mask layer 208 may be deposited by low pressure chemical vapor deposition on the basis of well-established recipes. Thereafter, a photolithography process may be performed to appropriately pattern the mask layer 208 in order to expose the first portion 204a while maintaining the second portion 204b covered.

FIG. 2c schematically shows the semiconductor device 200 after the completion of the above described photolithography process and after etch and clean processes for removing the first portion 204a, thereby exposing the surface 213a of the first semiconductor region 203a.

FIG. 2d schematically shows the device 200 after the formation of a second dielectric layer 214 having a portion 214a that covers the first semiconductor region 203a. The remainder of the second dielectric layer 214 may cover at least the surface portions of the mask layer 208b. In one particular embodiment, the second dielectric layer 214 comprises an oxide, such as silicon dioxide, while in other embodiments the second dielectric layer may comprise, additionally or alternatively, other dielectric materials such as silicon oxynitride, silicon nitride or even dielectrics having a moderately high permittivity. Irrespective of the specific material composition of the dielectric layer 214, in one illustrative embodiment, the dielectric layer 214 may be formed in accordance with design rules specifying a prescribed target thickness at least for the layer portion 214a. In this embodiment, the portion 214a may have a specified thickness 205a selected to substantially correspond to the target thickness, thereby endowing the desired characteristics to a circuit element to be formed on the dielectric layer portion 214a. As previously pointed out, gate insulation layers of sophisticated transistor elements may typically be formed on the basis of silicon dioxide, thereby requiring a thickness of 2 nm and even less within a process margin range of a few tenths of an Angstrom. Hence, in these particular embodiments, the thickness 205a may represent a silicon oxide based gate insulation layer having the required thickness of 2 nm or less.

A typical process flow for forming the device as shown in FIG. 2d may comprise any appropriate and well controllable oxidation process as it is also described with reference to the first dielectric layer 204b. Hence, the second dielectric layer 214 may be formed by a thermal oxidation process in a well-controlled oxidizing ambient to achieve the thickness 205a with the required accuracy. It should be noted that a thickness of the second dielectric layer 214 formed on the mask layer 208b does not necessarily need to be identical to the thickness 205a, since the material of the mask layer 208b may have a quite different oxidation rate, if at all, compared to the semiconductor region 203a. In those particular embodiments, in which the mask layer 208b comprises polysilicon, a somewhat differing oxidation rate may for instance occur due to the difference in crystallinity between the region 203a and the polysilicon 208b. In other embodiments, the second dielectric layer 214 may be formed by wet chemical oxidation on the basis of well-known chemicals. In still other embodiments, the dielectric layer 214 may be formed by an appropriate deposition process or by a combination of an oxidation process and a deposition process. Moreover, in any of these embodiments, a further treatment of the dielectric layer 214 may be performed, irrespective of whether this layer has been formed by oxidation and/or deposition. For instance, the dielectric layer 214 may be treated in a nitrogen-containing plasma ambient to incorporate a specific amount of nitrogen into the layer 214.

It should be noted that, in particular applications, the thickness 205b of the dielectric layer portion 204b is different compared to the thickness 205a of the portion 214a, as typically different characteristics are required at the regions 210a and 210b. In other embodiments, however, the thicknesses 205a and 205b may be substantially identical, whereas other characteristics of the layer portions 214a and 204b are varied to provide different characteristics for the respective layer. For instance, the material composition of the basic layers and/or the amount of introduced species may differ between the layers 214a and 204b. Moreover, certain differences in characteristics may be obtained by applying different formation processes for the first dielectric layer 204b and the second dielectric layer 214. Irrespective of the type of difference created between the layers 214a and 204b, the mask layer 208b efficiently decouples the manufacturing process for the first and second dielectric layers 204b and 214a, thereby providing an enhanced flexibility in adapting the characteristics of one of the layers 214a and 204b to specific device or process requirements without requiring a change of the process flow with respect to the other dielectric layer. In particular embodiments, when the first dielectric layer 204b and the second dielectric layer 214a are formed by oxidation processes, the mask layer 208b, even if it is comprised of polysilicon, effectually acts as an oxidation diffusion block as only a surface portion thereof is oxidized.

FIG. 2e schematically shows the semiconductor device 200 in a further advanced manufacturing stage. Here, an electrode material layer 208c, which may represent a gate electrode material in one embodiment, is deposited over the first and second semiconductor regions 203a and 203b. In particular embodiments, the electrode material 208c comprises polysilicon which in some embodiments may be doped with a specified dopant material to provide a substantially homogeneous dopant distribution within the layer 208c. The electrode material layer 208c may be deposited by well-established deposition techniques such as low pressure chemical vapor deposition if the layer 208c comprises polysilicon. During the deposition, the process is controlled to obtain a thickness 208h of the layer 208c which is greater than a design thickness for an electrode to be formed on the dielectric layer 214a. After the deposition of the layer 208c, the excess material thereof may be removed, for instance, by chemical mechanical polishing (CMP) or by a combination of etching and polishing.

FIG. 2f schematically shows the device 200 after completion of a final CMP process. Thus, the device 200 now comprises a substantially planarized surface 208s formed by the remainder of the electrode material layer 208c which is now indicated as 208a, and the remainder of the portion 208b wherein these two portions are separated by the residue of the second dielectric layer 214. Moreover, the planarizing process may be controlled to obtain a thickness of the portions 208a and 208b that corresponds to a design thickness 208d. In particular embodiments, the thickness 208d substantially corresponds to a height of gate electrodes to be formed from the portions 208a and 208b. As previously pointed out, the portions 208a and 208b may be both provided with different characteristics, for instance different type of electrode material and/or different types of dopant incorporated therein, to provide for different characteristics of respective electrodes, such as gate electrodes formed therefrom, even though the design thickness 208d is substantially identical for both the layer 208a and the layer 208b. Moreover, in combination with the potential for independently targeting the characteristics of the dielectric layer portions 214a and 204b, the overall performance of the respective circuit elements such as transistors and/or capacitors may be specifically tuned in accordance with design or process requirements individually for each device region 210a and 210b. In particular embodiments, gate insulation layers having different thicknesses may be fabricated, wherein each of the thicknesses may be adapted without any redesign of the process flow with respect to the non-involved gate insulation layer.

Moreover, in the embodiments shown in FIGS. 2a-2f, the process flow is shown in conjunction with the semiconductor device 200 in which the first dielectric layer is formed to have an increased thickness 204b compared to the finally obtained dielectric layer 214a. In other embodiments, in which dielectric layers of different thicknesses are required, the dielectric layer 214 may be formed as an initial dielectric layer (see FIG. 2a) to first form the thinner dielectric layer. Thereafter, the process flow as shown in FIGS. 2b-2f may be continued in a similar fashion, whereas, however, in FIG. 2d, the second dielectric layer is now formed to have the characteristics of a thicker dielectric layer. In such a process flow, the initially thin dielectric layer formed on the semiconductor region 203b has not experienced a preceding etch process as is the case for the region 203a prior to receiving the thin dielectric layer 214a. Consequently, in this reverse process, the ultra-thin dielectric layer, which may be quite sensitive to any surface defects, is formed on a surface portion of the underlying semiconductor region that has experienced fewer processes and therefore may provide the potential for a reduced overall defect rate in forming gate insulation layers.

Starting from the semiconductor device 200 as shown in FIG. 2f, further processing may then be continued with the formation of electrodes, in particular embodiments, gate electrodes, on the respective layers 214a and 204b. In some embodiments, prior to well-established patterning processes for gate electrodes or any other circuit elements, the remainder of the layer 214, indicated as 214r, may be removed, at least partially, by a corresponding etch process. For example, if the residual 214r of the layer 214 is comprised of silicon dioxide, a highly selective wet chemical process may be performed to remove at least a portion thereof when the residual portion 214r is considered inappropriate for the further processing of the device 200. Thereafter, any gaps obtained by removing at least a portion of the residual portion 214r of the layer 214 may be filled, at least partially during a subsequent process for forming an anti-reflective coating (ARC) as is typically used in patterning gate electrodes.

With reference to FIGS. 2g-2h, further illustrative embodiments in forming the device 200 will be described, wherein the size of the residual portion 214r (FIG. 2f) is significantly reduced.

In FIG. 2g, the semiconductor device 200 comprises essentially the same components as are shown in FIG. 2b, wherein, however, a thickness 208t of the mask layer 208 is significantly reduced compared to the layer 208 of FIG. 2b. That is, the layer 208 of FIG. 2g has a thickness that is significantly less than a design height of any electrode to be formed on the dielectric layer portion 204b. Thus, the thickness 208t of FIG. 2g is designed to provide a sufficient blocking effect during a subsequent formation of a second dielectric layer on the semiconductor region 203a (FIG. 2d) and to provide a sufficient process margin during a CMP process to remain a required minimum portion of the layer 208 above the dielectric layer portion 204b. For instance, the layer 208 of FIG. 2g may be deposited with a thickness of approximately 20-80 nm depending on the process requirements. After the deposition of the layer 208, further processing may be continued as is also described with respect to FIG. 2c. That is, the mask layer 208 is patterned to expose the semiconductor region 203a which is then cleaned and prepared for receiving a further dielectric layer thereon.

FIG. 2h schematically shows the device 200 after forming the second dielectric layer 214 including the layer portion 214a. Moreover, the electrode material layer 208c is formed above the second dielectric layer 214, wherein, advantageously, the layer 208c is also provided with a reduced thickness compared to the device 200 as shown in FIG. 2e. That means, the layer 208c may be provided with a thickness that is significantly less than a design height of an electrode structure to be formed on the dielectric layer portion 214a. For example, the layer 208c may be provided with a thickness of approximately 20-80 nm. Thereafter, a CMP process may be performed to planarize the surface and to remove the dielectric layer 214 above the dielectric layer 204b while maintaining a desired minimum portion of electrode material on the layer portions 214a and 204b. Thus, the CMP process may be stopped well above the dielectric layers 204b and 214a, as is indicated by the dashed line 209, thereby providing electrode material with a thickness 208h on the respective dielectric layers. At the same time, the residual of the second dielectric layer 214, i.e., the portion 214r, is significantly reduced in height so that the further processing of the device 200 may be continued substantially without any influence that may otherwise be caused by the presence of the portion 214r. That is, in some embodiments, a further electrode material may be deposited to obtain the final desired target height of any electrode to be patterned on the dielectric layers 214a and 204b. In other embodiments, the portion 214r of the reduced height may be completely removed by a corresponding etch process which may then be followed by the further deposition of electrode material. Consequently, the embodiments shown with reference to FIGS. 2g and 2h provide even more flexibility in forming dielectric layers with different characteristics such as gate insulation layers with different thicknesses, in that the device regions 210a and 210b may even represent closely spaced regions without requiring significant modifications of design rules, which may otherwise be necessary for devices including the portion 214r as is shown in FIG. 2f.

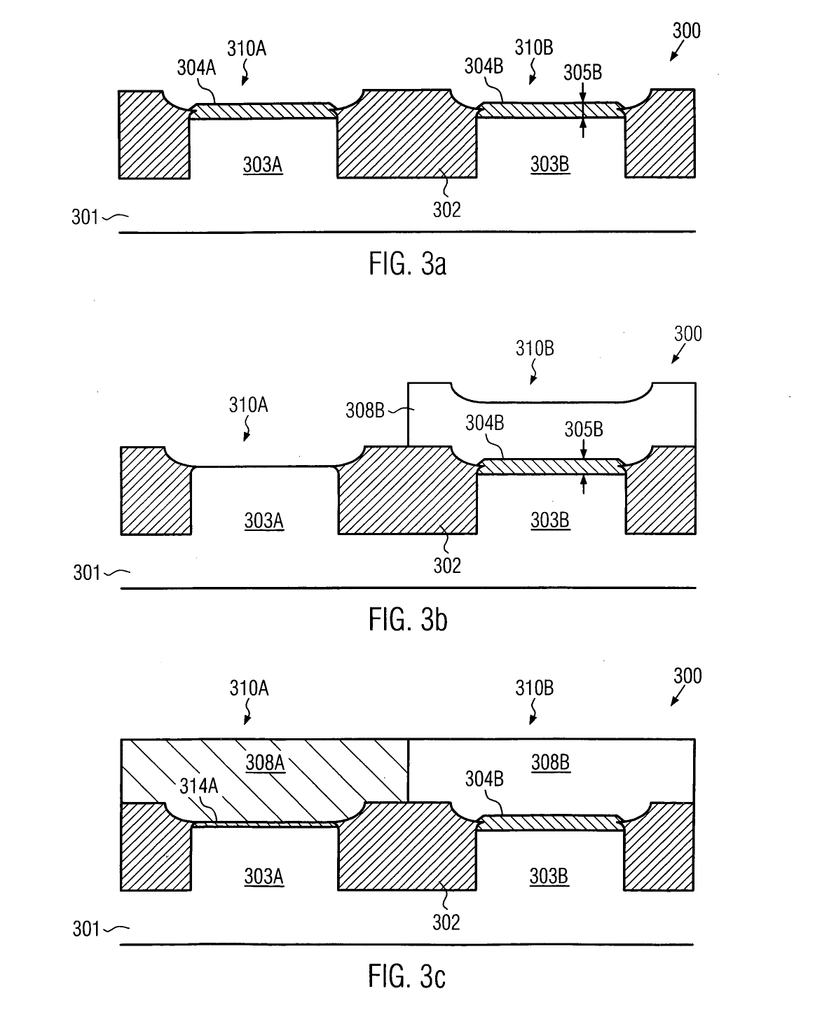

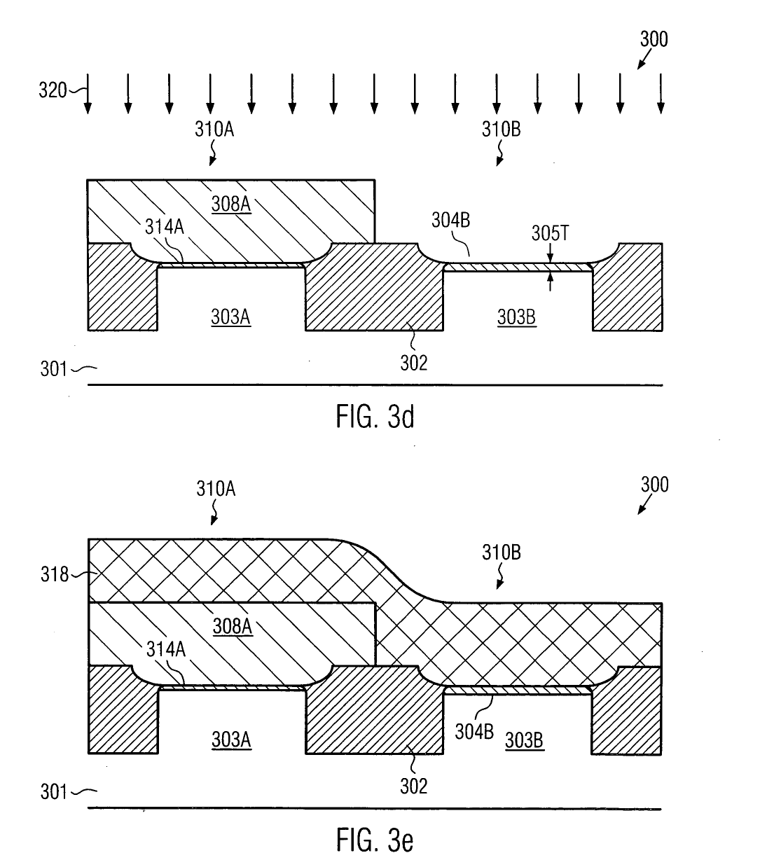

With reference to FIGS. 3a-3e, further illustrative embodiments will now be described, wherein any remaining portions of the second dielectric layer, such as the portion 214r (FIG. 2f), may be avoided.

In FIG. 3a, a semiconductor device 300 comprises a substrate 301 having formed thereon first and second regions 310a and 310b. The regions 310a and 310b may represent closely spaced regions such as neighboring regions for specific transistor elements and the like, or they may represent regions assigned for different functional blocks to be formed within a die area of the substrate 301. The regions 310a and 310b may be separated by an intermediate area or an isolation structure 302 which may be provided in the form of a shallow trench isolation. The region 310a may comprises a crystalline semiconductor region 303a having formed thereon a dielectric layer portion 304a. Similarly, the region 310b may comprise a crystalline semiconductor region 303b having formed thereon a dielectric layer portion 304b. As previously explained, the dielectric layer portions 304a and 304b may represent a first dielectric layer that is formed in a common manufacturing process. Regarding the composition and/or the formation of the portions 304a and 304b the same criteria apply as previously pointed out with reference to the layers 104a, 104b, 204a, and 204b. In some embodiments, a thickness of the portion 304b, indicated as 305d, is greater than a target thickness of a dielectric layer to be formed on the semiconductor region 303b. Moreover the dielectric layer 308 may represent any appropriate dielectric layer. For instance, the layer 308 may represent a silicon dioxide layer, a silicon nitride layer, and the like.

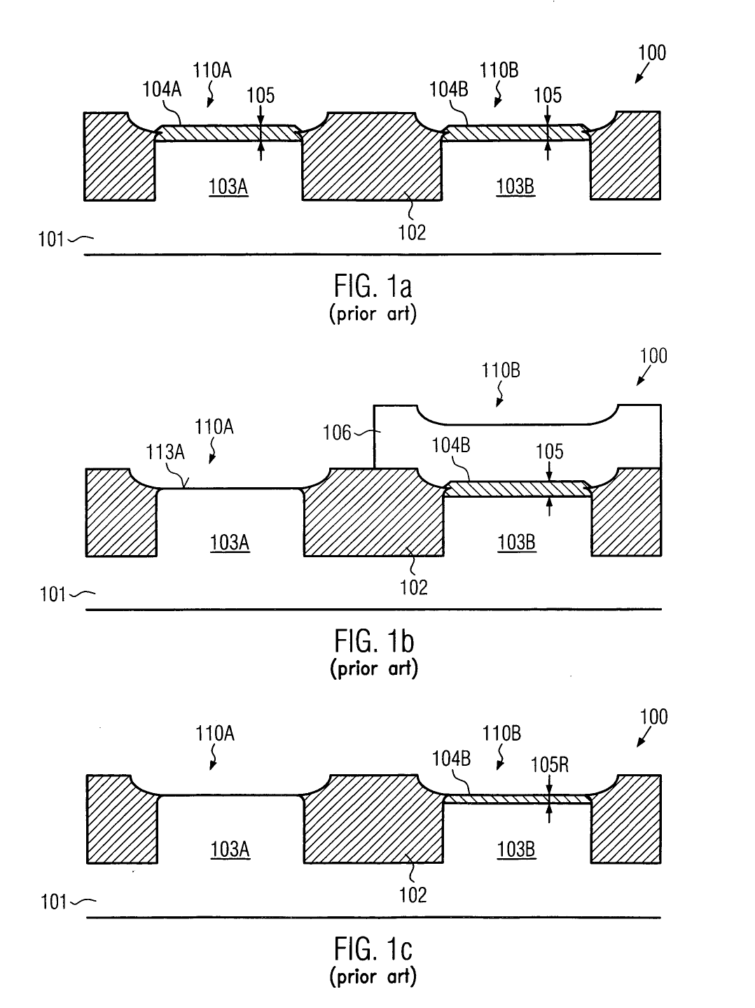

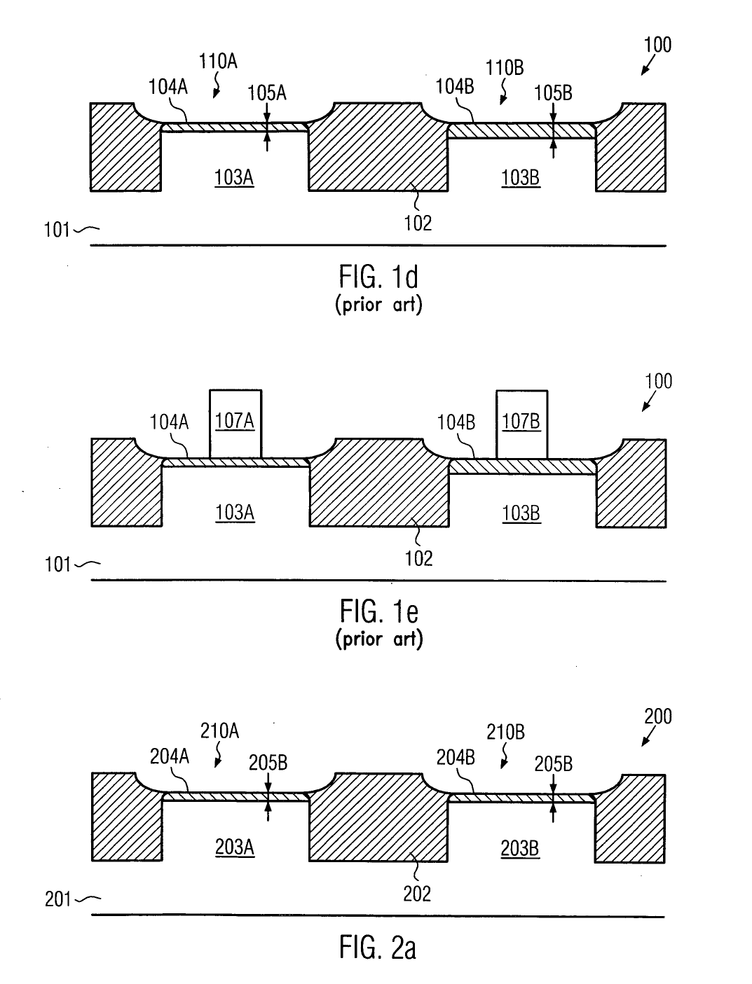

The device 300 as shown in FIG. 3a may be formed in accordance with well-established process techniques as are also described with reference to FIGS. 1a and 2a, wherein the mask layer 308 may be formed by well-established plasma enhanced chemical vapor deposition techniques. Thereafter, photolithography and etch processes may be applied to pattern the mask layer 308 to expose the semiconductor region 303a. Thereafter, the dielectric layer portion 304a may be removed by any clean processes as is also described with reference to FIGS. 2b and 2c.

FIG. 3b schematically shows the device 300 after the completion of the above-described process steps. Thus, the device 300 comprises the patterned layer 308, now indicated as 308b, covering the dielectric layer 304b and exposing the semiconductor region 303a prepared to receive a second dielectric layer thereon. In this embodiment, the device 300 is exposed to an oxidizing ambient to form on oxide layer on the exposed semiconductor region 303a. Due to the dielectric nature of the mask layer 308b which may, for instance be comprised of silicon nitride, an oxidation of the portion 308b is substantially prevented. After oxidizing the substrate 301, a first electrode material may be deposited to cover the oxidized semiconductor region 303a and the mask layer 308b.

FIG. 3c schematically shows the semiconductor device 300 after completion of the above-described process sequence and after a subsequent CMP process for planarizing the resulting structure. Hence, the device 300 comprises a planarized electrode material layer 308a formed on a dielectric layer 314a comprising an oxidized portion. Is should be appreciated that the dielectric layer 314a, although basically formed by an oxidation process, may further be treated to adjust the characteristics thereof. For instance, nitrogen may have been incorporated into the oxide layer to provide the required charge carrier blocking effect. Next, the mask layer 308b may selectively be removed to expose the dielectric layer portion 304b. Corresponding selective etch recipes are well established for silicon nitride, silicon and silicon dioxide and may be used for this purpose. In other embodiments, an additional resist mask (not shown) may be formed to substantially cover the layer 308a while removing the mask layer 308b. During the removal of the mask layer 308b and/or after the removal process, a portion of the dielectric layer portion 304b may also be removed in a highly controlled fashion to precisely adjust a thickness thereof to a desired target thickness.

FIG. 3d schematically shows the device 300 during an etch process 320 that is performed to reduce the thickness 305b of the layer 304b, i.e., the etching process is performed to achieve a thickness of the dielectric layer portion 304b that substantially corresponds to a target thickness 305t. It should be appreciated that the process parameters of the etch process 320 may be obtained on the basis of corresponding etch procedures so that the thickness 305t may be adjusted with the required accuracy. Moreover, any redesign of one of the dielectrics 314a and 304b may be performed individually without requiring any process modifications for forming the other dielectric layer as is also the case for the embodiments previously described. After adjusting the thickness 305t of the dielectric layer 304b, a second electrode material may be deposited.

FIG. 3e schematically shows the device 300 after the formation of a second electrode material layer 318, which, in some embodiments, may be the same material as comprised in the layer 308a, whereas, in other embodiments, the material of the layer 318 may have different characteristics compared to the layer 308a. For example, the layers 308a and 318 may represent differently doped polysilicon layers to provide different electrical performance with respect to circuit elements to be formed in the regions 310a and 310b. After the deposition of the electrode material layer 318, a CMP process may be performed to remove excess material and planarize the resulting structure. Thereafter, further processing may be continued by patterning respective electrode structures on the dielectric layers 314a and 304b as is also described with reference to FIG. 2f.

Moreover, it should be appreciated that the above sequence may be performed repeatedly to form three or more different types of dielectric layers. For instance, the mask layer 308b may be patterned in such a way that it covers two or more different types of device regions, which may then be successively exposed by providing respective resist masks during the etch process 320, thereby enabling a different degree of adaptation in the sequentially exposed device regions.

As a result, the present invention provides an enhanced technique for forming different types of dielectric layers and, in particular, provides different types of gate insulation layers, wherein the individual manufacturing processes are high decoupled so that process modifications in view of design requirements may readily be performed on one type of dielectric layer substantially without affecting the manufacturing of the other type of dielectric layer. In particular embodiments, gate insulation layers of different thickness may be formed in a highly decoupled fashion, thereby providing the potential for an individual fine-tuning of each critical formation process such as an oxidation process and also improving the non-uniformity of the overall process.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a first dielectric layer having a first specified characteristic on a first semiconductor region and a second semiconductor region, said first and second semiconductor regions formed on a substrate;
forming a mask layer above said substrate to expose a first portion of said first dielectric layer located above said first semiconductor region and to cover a second portion of said first dielectric layer located above said second semiconductor region;
removing said first portion of said first dielectric layer; and
forming a second dielectric layer with a second specified characteristic on said first semiconductor region, said first characteristic differing from said second characteristic and said mask layer preventing said second dielectric layer from forming on said second portion of said first dielectric layer.

2. The method of claim 1, wherein forming said first dielectric layer comprises exposing said substrate to an oxidizing ambient to oxidize a portion of said first and second semiconductor regions.

3. The method of claim 1, wherein forming said first dielectric layer comprises depositing a first dielectric material.

4. The method of claim 1, further comprising depositing a layer of a first electrode material above said first and second semiconductor regions.

5. The method of claim 4, wherein said layer of a first electrode material has a thickness that is greater than a design height of a first gate electrode to be formed above said first semiconductor region.

6. The method of claim 4, wherein forming said mask layer comprises depositing a layer of a second electrode material.

7. The method of claim 6, wherein a thickness of said layer of a second gate electrode material is greater than a design height of a second gate electrode to be formed above said second semiconductor region.

8. The method of claim 1, wherein forming said second dielectric layer comprises exposing said substrate to an oxidizing ambient.

9. The method of claim 1, wherein forming said second dielectric layer comprises depositing a second dielectric material.

10. The method of claim 6, further comprising removing excess material of said first dielectric layer.

11. The method of claim 10, further comprising planarizing the layer of a first gate electrode material and the mask layer to provide a substantially flat first gate electrode layer above said first semiconductor region and a substantially flat second gate electrode layer above said second semiconductor region.

12. The method of claim 1, wherein said first characteristic represents a first thickness corresponding to a design thickness of an insulation layer of a circuit element to be formed above said second semiconductor region.

13. The method of claim 1, wherein said second characteristic represents a second thickness corresponding to a design thickness of an insulation layer of a circuit element to be formed above said first semiconductor region.

14. The method of claim 1, wherein said first and second characteristics represent a first and a second thickness, respectively, and said second thickness is less than said first thickness.

15. The method of claim 1, wherein said first and second characteristics represent a first and a second thickness, respectively, and said first thickness is less than said second thickness.

16. The method of claim 1, wherein said first and second characteristics represent a first and a second thickness, respectively, and said second thickness is less than approximately 2 nm.

17. The method of claim 1, wherein said first semiconductor region is located in a first die region assigned to a first functional block to be formed and said second semiconductor region is located in a second die region assigned to a second functional block to be formed in said second die region.

18. The method of claim 4, further comprising removing excess material of said first electrode material above said second semiconductor region to expose said mask layer and removing said mask layer.

19. The method of claim 18, further comprising reducing a thickness of said second portion to obtain a value corresponding to a final desired value.

20. The method of claim 19, further comprising depositing a layer of a second electrode material and removing excess material of said layer of a second electrode material to expose said first electrode material formed above said first semiconductor region.

21. The method of claim 1, wherein said first and second characteristics differ in material composition.
